(19) United States
(12) Patent Application Publication
(10) Pub. No.: US 2023/0066696 A1
(43) Pub. Date: Mar. 2, 2023

(54) INFORMATION PROCESSING APPARATUS AND CONTROL METHOD

(71) Applicant: Lenovo (Singapore) Pte. Ltd., Singapore (SG)

(72) Inventors: Yusuke Taira, Kanagawa (JP); Takashi Sugawara, Kanagawa (JP)

(73) Assignee: Lenovo (Singapore) Pte. Ltd., Singapore (SG)

(21) Appl. No.: 17/851,557

(22) Filed: Jun. 28, 2022

(30) Foreign Application Priority Data
Aug. 26, 2021 (JP) 2021-137985

(51) Int. Cl. G11C 5/14

(52) U.S. Cl. CPC G11C 5/147; G11C 2207/2227

(57) ABSTRACT

An information processing apparatus includes a first processor that executes a hardware startup process, a second processor separate from the first processor, and a memory interface which includes a temperature sensor, the memory interface being configured to interface with a memory, wherein the memory interface is configured to, when a temperature sensed by the temperature sensor reaches a predetermined temperature threshold value, throttle performance of the memory, the first processor executing the hardware startup process includes transmitting a plurality of temperature threshold values to the memory interface via a first interface, and the second processor, in response to an event, transmits selection information to the memory interface via a second interface different from the first interface, the selection information indicating selection of one of the plurality of temperature threshold values to be set as the predetermined temperature threshold value.

### CROSS-REFERENCE TO RELATED APPLICATIONS

This application claims priority to Japanese Patent Application No. 2021-137958 filed on Aug. 26, 2021, the contents of which are hereby incorporated herein by reference in their entirety.

### TECHNICAL FIELD

The present disclosure relates to an information processing apparatus and a control method.

### BACKGROUND

Nowadays, there is a tendency toward use of a memory drive device such as an SSD (Solid State Drive) and others which are advantageous due to high access speed. There is room for improvement regarding heat management of such memory drive devices.

### SUMMARY

In one aspect of the present disclosure, an information processing apparatus includes a first processor that executes a hardware startup process, a second processor separate from the first processor, and a memory interface which includes a temperature sensor, the memory interface being configured to interface with a memory, wherein the memory interface is configured to, when a temperature sensed by the temperature sensor reaches a predetermined temperature threshold value, throttle performance of the memory, the first processor executing the hardware startup process includes transmitting a plurality of temperature threshold values to the memory interface via a first interface, and the second processor, in response to an event, transmits selection information to the memory interface via a second interface different from the first interface, the selection information indicating selection of one of the plurality of temperature threshold values to be set as the predetermined temperature threshold value.

### BRIEF DESCRIPTION OF THE DRAWINGS

FIG. 1 is a perspective view illustrating one example of an outer appearance of an information processing apparatus according to one embodiment of the present disclosure.

FIG. 2 is a plan view schematically illustrating one example of inside of an instrument chassis of the information processing apparatus according to one embodiment of the present disclosure.

FIG. 3 is a diagram illustrating one example of a relation between a change in temperature in the SSD and the performance of the SSD.

FIG. 4 is a block diagram illustrating one example of a hardware configuration of the information processing apparatus according to one embodiment of the present disclosure.

FIG. 5 is a block diagram illustrating one example of a functional configuration of the information processing apparatus according to one embodiment of the present disclosure.

FIG. 6 is a flowchart illustrating one example of DITT (Device Initiated Thermal Throttling Threshold) setting processing according to one embodiment of the present disclosure.

FIG. 7A is a diagram illustrating an example of a use state (usage form) of the information processing apparatus according to one embodiment of the present disclosure.

FIG. 7B is a diagram illustrating an example of a use state (usage form) of the information processing apparatus according to one embodiment of the present disclosure.

FIG. 7C is a diagram illustrating an example of a use state (usage form) of the information processing apparatus according to one embodiment of the present disclosure.

### DETAILED DESCRIPTION

In the following, one embodiment of the present disclosure will be described in detail with reference to the drawings.

First, an outline of an information processing apparatus according to one embodiment of the present disclosure will be described.

### Outline of Information Processing Apparatus

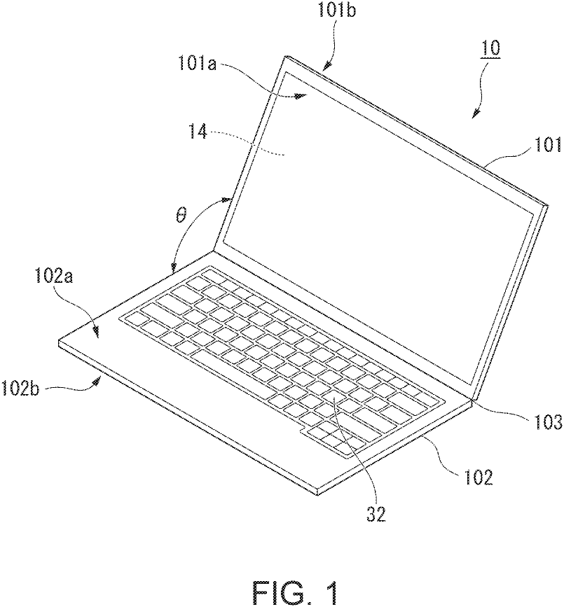

With the use of SSDs, although performance improvement is promoted, there is such an issue that an amount of heat which is generated from the memory drive device is increased. As the amount of heat which is generated from the memory drive device is increased, a surface temperature of a chassis of the information processing apparatus that the memory drive device is loaded is increased accordingly. Since the surface temperature of the chassis is defined to be less than a constant temperature on the basis of safety standards such as the UL (Underwriters Laboratories) standards and so forth, it is necessary to suppress temperature rising. In this regard, FIG. 1 is a perspective view illustrating one example of an external appearance of the information processing apparatus according to one embodiment of the present disclosure.

The information processing apparatus 10 which is illustrated in FIG. 1 is a clamshell-shape laptop PC (Personal Computer). The information processing apparatus 10 includes a display chassis 101 that a display section 14 (a display) is loaded, an instrument chassis 102 that a keyboard 32 is loaded and a hinge mechanism 103. The display chassis 101 and the instrument chassis 102 are almost quadrangular and plate-shaped (for example, tabular) chassis.

One side face of the display chassis 101 and one side face of the instrument chassis 102 are connected (coupled) together via the hinge mechanism 103 and the display chassis 101 and the instrument chassis 102 are rotationally movable relatively around an axis of rotation that the hinge mechanism 103 defines. A state where an opening angle θ around the axis of rotation of the display chassis 101 and the instrument chassis 102 is about 0° is a state (referred to as a “closed state”) where the display chassis 101 and the instrument chassis 102 are mutually closed in a superposed state. A state where the display chassis 101 and the instrument chassis 102 are mutually opened in opposite directions is referred to as an “opened state” relative to the closed state. The opened state is a state where the display chassis 101 and the instrument chassis 102 are rotationally moved relatively until the opening angle θ becomes larger than a threshold value (for example, 10°) which is set in advance. The outer appearance of the information processing apparatus 10 which is illustrated in FIG. 1 indicates one example of the opened state.

In the example in FIG. 1, a surface of the display chassis 101 that the display section 14 is installed will be referred to as a display surface 101a and a surface which is opposite to the display surface 101a will be referred to as a top surface 101b. In addition, a surface of the instrument chassis 102 that a keyboard 32 is installed will be referred to as a keyboard surface 102a and a surface which is opposite to the keyboard surface 102a will be referred to as a bottom surface 102b. The display surface 101a and the keyboard surface 102a are surfaces which are located on mutually facing sides of the display chassis 101 and the instrument chassis 102 in the closed state. In the example which is illustrated in FIG. 1, the keyboard 32 is a physical keyboard that a plurality of keys (one example of operators) which accepts an operation of a user is arrayed. Incidentally, a touch pad and so forth may be installed on the keyboard surface 102a other than the keyboard 32.

Since the display surface 101a of the display chassis 101 and the keyboard surface 102a of the instrument chassis 102 are superposed facing each other in the closed state, the information processing apparatus 10 enters a state where it becomes impossible for the user to visually recognize the display section 14 and, in addition, enters a state it becomes impossible for the user to operate the keyboard 32. On the other hand, in the opened state, the information processing apparatus 10 enters a state where it becomes possible for the user to visually recognize the display section 14 and, in addition, enters a state where it becomes possible for the user to operate the keyboard 32.

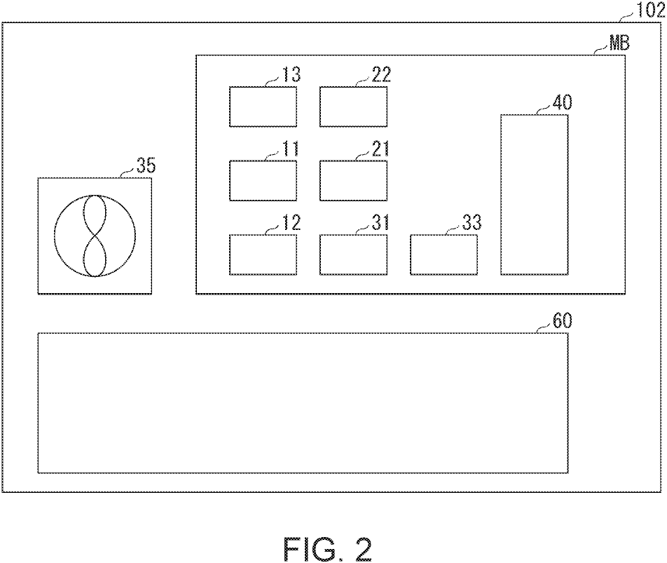

FIG. 2 is a plan view schematically illustrating one example of inside of the instrument chassis 102 of the information processing apparatus 10 according to one embodiment of the present disclosure. In the instrument chassis 102, a mother board MB, a battery 60, a heat radiation fan 35 and so forth are arranged. For example, a CPU (Central Processing Unit) 11, a main memory 12, a video subsystem 13, a chipset 21, a BIOS (Basic Input Output System) memory 22, an embedded controller 31, a power source circuit 33, an SSD (Solid State Drive) 40 and so forth are mounted on the mother board MB.

The CPU 11 may be a CPU-GPU (Graphics Processing Unit) combo or may be either the CPU or the GPU. The CPU 11 may be of a type that the CPU and the GPU are formed to have a common core. Further, the CPU 11 may be of a type that the CPU and the GPU are formed to have mutually different cores thereby to share a load thereon. In addition, a plurality of CPUs 11 may be installed.

The SSD 40 is a memory drive device which is connected as a storage area (a memory area) of the information processing apparatus 10. The SSD 40 is high in access speed in comparison with an HDD (Hard Disk Drive) and promotes improvement of performance and, on the other hand, also an amount of heat which is generated from the SSD 40 is increased as the performance is improved. In a case where the temperature of the SSD 40 rises, control that the performance of the SSD 40 is degraded thereby to suppress temperature rising (the temperature is lowered) is generally made for fault avoidance of the SSD 40 itself and safety ensuring of the user. For example, the information processing apparatus 10 has a function of monitoring the temperature of the SSD 40 by using a temperature sensor which is installed in the SSD 40, degrading the performance in a case where the temperature reaches a predetermined temperature threshold value and thereby suppressing the temperature rising (hereinafter, referred to as a “thermal throttling function).

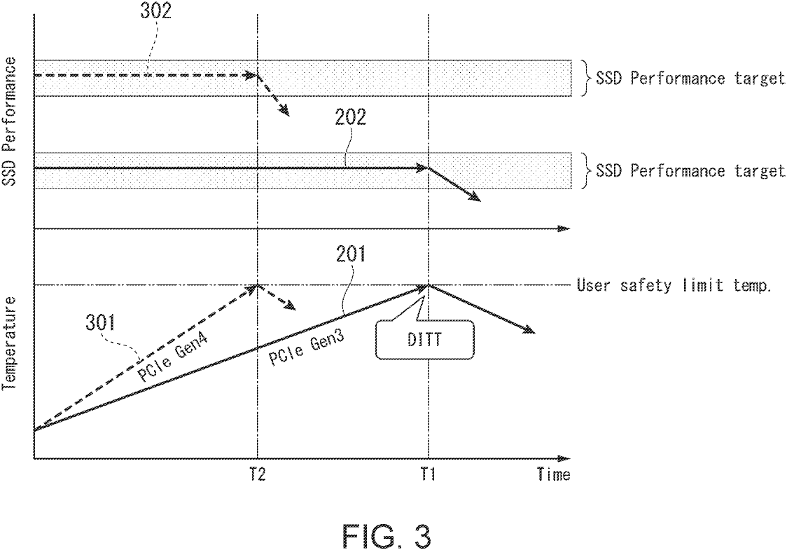

FIG. 3 is a diagram illustrating one example of a relation between a temperature change and the performance of the SSD 40. In FIG. 3, the horizontal axis indicates a time and the vertical axis indicates the temperature of the SSD 40 and the performance (an access speed) at the time of gaining access to the SSD 40. A solid line 201 indicates the temperature change of the SSD 40 which is based on PCIe Gen 3 (PCI Express 3.0) and a solid line 202 indicates the performance which corresponds to the temperature change. No limit is set on the performance until reaching a temperature (User safety limit temp) that the safety of the user is ensured and the temperature of the SSD 40 gradually rises in accordance with the progress state of access to the SSD 40. In a case where the temperature of the SSD 40 reaches a predetermined temperature threshold value (hereinafter, referred to as “DITT: Device Initiated Thermal Throttling Threshold:”), the performance of the SSD 40 is degraded step by step to lower the temperature of the SSD 40 by using the thermal throttling function so as not to exceed the temperature that the safety of the user is ensured.

In a case where an SSD 40 which is based on PCIe Gen 4 (PCI Express 4.0) which is set faster than PCIe Gen 3 in access speed is used, there is a tendency that the amount of heat which is generated is more increased and the temperature rises more rapidly. The temperature change of the SSD 40 which is based on PCIe Gen 4 is indicated by a broken line 301 and the performance which corresponds to the temperature change is indicated by a broken line 302. As illustrated in FIG. 3, in the SSD 40 which is based on PCIe Gen 4, since the temperature of the SSD 40 reaches DITT at a timing (a time T2) which is earlier than a timing that the temperature of the SSD 40 which is based on PCIe Gen 3 reaches DITT, it becomes necessary to degrade the performance of the SSD 40 which is based on PCIe Gen 4 at an earlier timing. However, in a case where the performance of the SSD 40 which is based on PCIe Gen 4 is degraded, it sometimes occurs that the performance becomes less than a target performance and comfortability which is attained when the user uses the information processing apparatus 10 is impaired.

For example, in the UL standards which are cited as standards which relate to the temperature to be set for ensuring the safety of the user, standard values of mutually different temperature limit values (maximum temperatures) are specified for a person’s contactable part and a person’s non-contactable part. The temperature limit value which is set for the person’s contactable part is specified to a value which is lower than the temperature limit value which is specified for the person’s non-contactable part in consideration of influence on human bodies. In a case where the SSD 40 (see FIG. 2) which is disposed in the instrument chassis 102 generates heat and the temperature in the instrument chassis 102 rises, mainly the temperature of the bottom surface 102b of the instrument chassis 102 rises. For example, in a case where the user uses the information processing apparatus 10 with the information processing apparatus 10 being placed on a desk, since the bottom surface 102b is in contact with the surface of the desk, the bottom surface 102b becomes the user’s non-contactable part. On the other hand, in a case where the user uses the information processing apparatus 10 with the information processing apparatus 10 being put on the user’s knees and so forth, the bottom surface 102b enters a state of being in contact with the user’s knees typically. The bottom surface 102b which is the most influenced by the heat that the SSD 40 generates becomes the user’s contactable part in one case and becomes the user’s non-contactable part in another case depending on a use state of the information processing apparatus 10 in this way.

However, in an existing information processing apparatus which is equipped with an existing thermal throttling function, since it is difficult to change the DITT after setting the DITT at system startup, the DITT is set so as not to exceed a lower temperature limit value (the temperature limit value for the person’s contactable part) with safety in mind. Therefore, in a case where the temperature of the SSD 40 reaches the DITT which is set so as not to exceed the temperature limit value for the person’s contactable part, the performance of the SSD 40 is degraded in any use state so far and the possibility that the comfortability which would be attained when the user uses the existing information processing apparatus would be impaired is high.

Accordingly, the information processing apparatus 10 according to one embodiment of the present disclosure makes it possible for the user to dynamically switch the DITT depending on the use state and so forth of the information processing apparatus 10 and thereby to suppress the performance degradation while suppressing the temperature rising of the SSD 40. For example, it is possible for the information processing apparatus 10 to decide whether the user is in a state of being contactable with the bottom surface 102b depending on the use state, to switch the DITT on the basis of a result of decision and thereby so as not to degrade the performance of the SSD 40 as much as possible while meeting the UL standards. In the following, a concrete configuration of the information processing apparatus 10 will be described.

### Hardware Configuration of Information Processing Apparatus 10

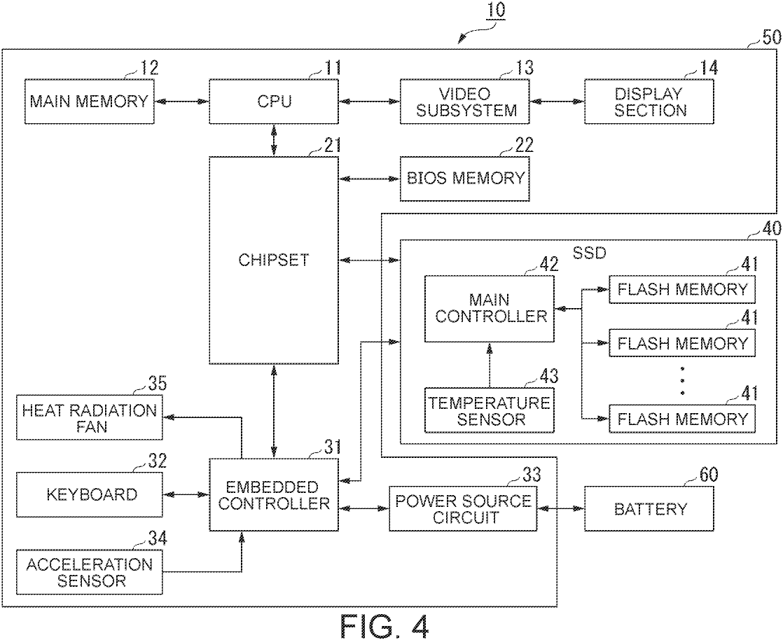

FIG. 4 is a block diagram illustrating one example of main hardware constitutional elements which configure the hardware configuration of the information processing apparatus 10 according to one embodiment of the present disclosure. As illustrated in FIG. 4, the information processing apparatus 10 includes a main control unit 50, the SSD 40 and a battery 60 which is used for power supply. The main control unit 50 includes the CPU 11, the main memory 12, the video subsystem 13, the display section 14, the chipset 21, the BIOS memory 22, the embedded controller 31, the keyboard 32, the power source circuit 33, an acceleration sensor 34 and the heat radiation fan 35.

The CPU 11 executes various kinds of arithmetic processing under program control and controls the entire operation of the information processing apparatus 10. For example, the CPU 11 executes processing which is based on programs such as an OS (Operating System), a BIOS and so forth.

The main memory 12 is a writable memory which is utilized as a read-in area of an execution program of the CPU 11 or a work area into which processing data on the execution program is to be written. The main memory 12 is configured by, for example, a plurality of DRAM (Dynamic Random Access Memory) chips. The OS, various drivers for hardware operations of peripherals, various services/utilities, application programs and so forth are contained in the execution program.

The video subsystem 13 is adapted to realize a function which relates to image display and includes a video controller. The video controller processes a drawing command which is sent from the CPU 11, writes drawing information which is obtained by processing the drawing command into a video memory and reads the drawing information out of the video memory and outputs the read-out drawing information to the display section 14 as drawing data (display data).

The display section 14 is, for example, a liquid crystal display, an organic EL display and so forth and displays a display screen which is based on the drawing data (the display data) which is output from the video subsystem 13.

The chipset 21 includes controllers for an USB (Universal Serial Bus), a serial ATA (AT Attachment) bus, an SPI (Serial Peripheral Interface) bus, a PCI (Peripheral Component Interconnect) bus, a PCI-Express bus, an LPC (Low Pin Count) bus and so forth and a plurality of devices is connected to the chipset 21 via these buses. In the example in FIG. 4, the BIOS memory 22, the SSD 40 and the embedded controller 31 are connected to the chipset 21 as examples of the plurality of devices.

The BIOS memory 22 is configured by an electrically rewritable nonvolatile memory such as, for example, an EEPROM (Electrically Erasable Programmable Read Only Memory), a flash ROM and so forth. The BIOS memory 22 stores the BIOS, system firmware which is adapted to control the operation of the embedded controller 31 and so forth and others.

The SSD 40 is one example of the memory drive device which includes a rewritable nonvolatile memory and stores the OS, the various drivers, the various services/utilities, the application programs and various data. The information processing apparatus 10 executes various information processing by utilizing the data that the SSD 40 stores. The SSD 40 is connected to the chipset 21 via, for example, the PCle bus. In addition, the SSD 40 is connected to the embedded controller 31 via, for example, an SMBus (System Management Bus).

As illustrated in FIG. 4, the SSD 40 includes a plurality of flash memories 41, a memory controller 42 and a temperature sensor 43. Each flash memory 41 is, for example, a NAND flash memory, that is, one example of the rewritable nonvolatile memory.

The memory controller 42 is a processor which includes, for example, not-illustrated CPU, ROM, RAM and so forth and controls the operation of the SSD 40 all-inclusively. The memory controller 42 communicates with the chipset 21 and the embedded controller 31 via mutually different interfaces. For example, the memory controller 42 includes an NVMe (Non Volatile Memory Express) interface which is used for communication with the chipset 21 which is connected to the memory controller 42 via the PCIe bus. The memory controller 42 communicates with the BIOS memory 22 which stores the BIOS which is executed by, for example, the CPU 11 via the chipset 21 using an NVMe interface (the NVMe I/F). In addition, the memory controller 42 includes an SMBus interface (the SMBus I/F) which is used for communication with the embedded controller 31 which is connected to the memory controller 42 via the SMBus. The memory controller 42 communicates with, for example, the embedded controller 31 using the SMBus interface.

In addition, the memory controller 42 is connected to the flash memories 41 via a memory interface (the memory I/F) and performs access controls such as data writing into the flash memories 41, data reading out of the flash memories 41 and so forth. In addition, the memory controller 42 monitors a temperature which is sensed by the temperature sensor 43 which is installed in the SSD 40 and executes the thermal throttling function. The memory controller 42 acquires, for example, a plurality (for example, two kinds) of DITT which is transmitted in accordance with activation of the BIOS as choices.

Then, the memory controller 42 executes the thermal throttling function by using any one of the plurality of DITTs which is acquired as a default and, in a case where the temperature which is sensed by the temperature sensor 43 reaches the DITT which is chosen, restricts access to the flash memory 41 so as to suppress temperature rising. In addition, after activation of the BIOS, the memory controller 42 switches the DITT which is to be used for execution of the thermal throttling function in accordance with an instruction from the embedded controller 31. Thereby, it becomes possible for the SSD 40 to dynamically switch the DITT which is to be used after activation of the BIOS. DITT switching control will be described in detail later.

The embedded controller 31 is a one-chip microcomputer (One-Chip Microcomputer) which monitors and controls operations of the various devices (the peripherals, sensors and so forth) as a processor which is different from the CPU 11 which executes an OS-dependent process and a BIOS-dependent process. The embedded controller 31 includes a CPU, a ROM, a RAM, A/D input terminals and D/A output terminals of a plurality of channels, a timer and digital input/output terminals which are not illustrated in FIG. 4. For example, the keyboard 32, the power source circuit 33, the acceleration sensor 34, the heat radiation fan 35 and so forth are connected to the embedded controller 31 via respective input terminals. The embedded controller 31 receives, for example, input information (operation signals) which is sent from the keyboard 32 and sensor signals which are sent from the acceleration sensor 34. In addition, the embedded controller 31 controls operations of the power source circuit 33, the heat radiation fan 35 and so forth. In addition, the embedded controller 31 includes an SMBus and is connected to the SSD 40 via the SMBus.

The keyboard 32 is an input device that a plurality of keys (one example of operators) which accepts user’s operations is arrayed. As illustrated in FIG. 1, the keyboard 32 is disposed on the keyboard surface 102a of the instrument chassis 102. The keyboard 32 outputs the input information (for example, each operation signal which indicates each key which is operated on the keyboard 32) which is input by a user’s operation to the embedded controller 31. Incidentally, as input devices other than the keyboard 32, optional input devices such as a pointing device, a touch pad and so forth may be installed on optional places.

The power source circuit 33 is configured by, for example, a DC/DC converter, a charge/discharge unit, an AC/DC adapter and so forth. For example, the power source circuit 33 converts a DC voltage which is supplied from an external power source or the battery 60 into voltages of a plurality of levels which is necessary for the operation of the information processing apparatus 10. In addition, the power source circuit 33 supplies electric power to respective constitutional elements of the information processing apparatus 10 on the basis of control from the embedded controller 31.

The acceleration sensor 34 is adapted to detect a motion of the information processing apparatus 10 and is installed in a chassis (for example, the instrument chassis 102) of the information processing apparatus 10. The acceleration sensor 34 detects a direction and an acceleration in accordance with a posture and the motion of the information processing apparatus 10 and outputs a sensor signal which includes a result of detection to the embedded controller 31. It becomes possible for the embedded controller to acquire information on the motion, an inclination and so forth of the information processing apparatus 10 by acquiring the sensor signal from the acceleration sensor 34.

### Functional Configuration of Information Processing Apparatus 10

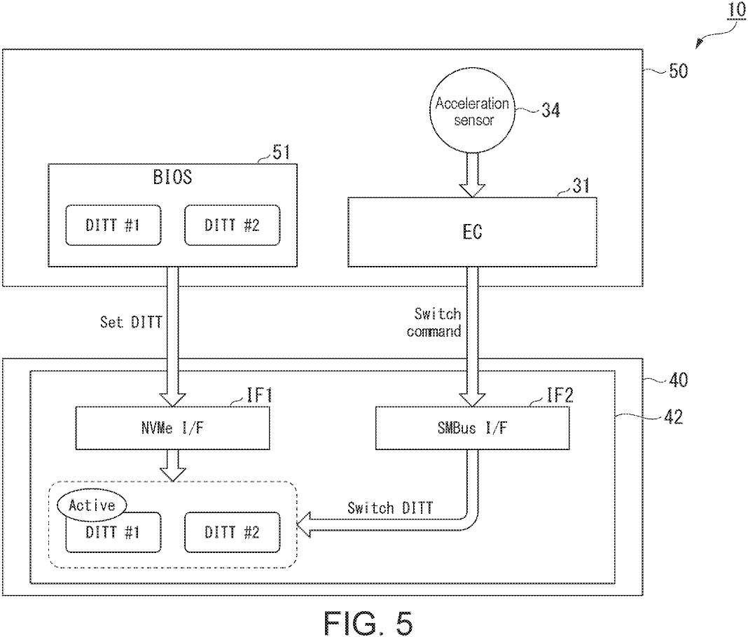

Next, a functional configuration which pertains to DITT setting of the thermal throttling function in the information processing apparatus according to one embodiment of the present disclosure will be described with reference to FIG. 5.

FIG. 5 is a block diagram illustrating one example of the functional configuration of the information processing apparatus 10 according to one embodiment of the present disclosure. Incidentally, in FIG. 5, only main functional constitutional elements which pertain to the DITT setting in the information processing apparatus 10 according to one embodiment of the present disclosure are illustrated. The information processing apparatus 10 includes the main control unit 50 and the SSD 40. The main control unit 50 includes a BIOS 51, the embedded controller (EC) 31 and the acceleration sensor 34.

The BIOS 51 is a functional constitutional element which is realized by execution of the BIOS which is stored in the BIOS memory 22 by the CPU 11 and functions to control startup of the hardware of the information processing apparatus 10. For example, the BIOS 51 functions to transmit DITT set information (Set DITT) which contains a plurality of temperature threshold values which are to be used as the choices for selection of the predetermined DITT to the memory controller 42 via an interface IF 1. Here, the interface IF 1 is, for example, the NVMe interface as described above. The BIOS 51 functions to transmit the DITT set information to the memory controller 42 via the interface IFI in a startup process.

In FIG. 5, an example that two kinds of DITTs, that is, a DITT #1 which is a first temperature threshold value and a DITT #2 which is a second temperature threshold value are contained in the DITT set information as the DITTs which are usable in the thermal throttling function is illustrated. The DITT #1 is a temperature threshold value which is set in advance in correspondence with a temperature limit value of the person’s contactable part, for example, in the UL standards and is set to a value which is less than one temperature limit value concerned. The DITT #2 is a temperature threshold value which is set in advance in correspondence with a temperature limit value of the person’s non-contactable part, for example, in the UL standards and is set to a value which is less than another temperature limit value concerned. The DITT #1 is set to a temperature threshold which is lower than the DITT #2.

The memory controller 42 acquires the DITT set information via the interface IFI and then sets the DITT #1 and DITT #2 which are contained in the acquired DITT set information as DITTs which are usable in the thermal throttling function. In addition, the memory controller 42 actively sets the DITT #1 as, for example, a default DITT. Thereby, the memory controller 42 executes the thermal throttling function by using the DITT #1. Incidentally, it is possible to optionally set a DITT which is to be actively set in a default state.

The embedded controller 31 transmits DITT selection information for selection of one DITT which is to be used in the thermal throttling function from among the choices of the plurality of DITT which is set in the memory controller 42 to the memory controller 42 via an interface IF 2. For example, the embedded controller 31 transmits a DITT switch command (Switch command) which indicates an instruction to switch the DITT to the memory controller 42 via the interface IF 2 as the DITT selection information for selection of one DITT which is to be used in the thermal throttling function in a case of changing from the currently set DITT to another DITT. Here, the interface IF 2 is, for example, the SMBus interface as described above. At least, selection information for selection of one DITT which is to be made active is contained in the DITT switch command. As one example, information which indicates at least the DITT #1 is contained in a DITT switch command which indicates the instruction to switch to the DITT #1 and information which indicates at least the DITT #2 is contained in a DITT switch command which indicates the instruction to switch to the DITT #2.

For example, the embedded controller 31 decides whether the user is in a state of being contactable with the bottom surface 102b of the information processing apparatus 10. Then, the embedded controller 31 selects one DITT which is to be used in the thermal throttling function from the DITT #1 and the DITT #2 which are set in the memory controller 42 on the basis of a result of decision of whether the user is in the state of being contactable with the bottom surface 102b.

For example, in a state where the DITT #1 which corresponds to the temperature limit value of the part with which the user is contactable in the default state, in a case where the embedded controller 31 decides that the user is in the state of not being contactable with the bottom surface 102b, the embedded controller 31 transmits a DITT switch command for switching from the DITT #1 to the DITT #2 to the memory controller 42 via the interface IF 2. In addition, in a case where the embedded controller 31 decides that the user is in the state of being contactable with the bottom surface 102b in a state where the DITT #2 is active, the embedded controller 31 transmits a DITT switch command for switching from the DITT #2 to the DITT #1 to the memory controller 42 via the interface IF 2.

The memory controller 42 acquires the DITT switch command via the interface IF 2 and then sets one DITT which is to be made active on the basis of the acquired DITT switch command. For example, in a case where the memory controller 42 acquires the DITT switch command for switching to the DITT #2, the memory controller 42 sets the DITT which is to be made active to the DITT #2. In addition, in a case where the memory controller 42 acquires the DITT switch command for switching to the DITT #1, the memory controller 42 sets the DITT which is to be made active to the DITT #1.

Next, a decision method that the embedded controller 31 decides whether the user is in the state of being contactable with the bottom surface 102b will be described. For example, the embedded controller 31 detects the use state of the information processing apparatus 10 and thereby decides whether the user is in the state of being contactable with the bottom surface 102b.

As one example, as illustrated in FIG. 5, the embedded controller 31 performs monitoring by acquiring the sensor signal from the acceleration sensor 34 and thereby decides the use state of the information processing apparatus 10 on the basis of a result of detection by the acceleration sensor 34. In a case where it is possible to decide that a value which indicates the motion of the information processing apparatus 10 is less than the predetermined value and the information processing apparatus 10 is in a stationary state, the embedded controller 31 decides that the user uses the information processing apparatus 10 in a state of placing the information processing apparatus 10 on the desk and so forth, that is, the user is in the state of not being contactable with the bottom surface 102b.

On the other hand, in a case where it is possible to decide that the value which indicates the motion of the information processing apparatus 10 is more than the predetermined value and the information processing apparatus 10 is in a not-stationary state (in a state where the information processing apparatus 10 is moving though slightly), the embedded controller 31 decides that the user uses the information processing apparatus 10 in the state of putting the information processing apparatus 10 on the user’ s knees, that is, the user is in the state of being contactable with the bottom surface 102b.

That is, the embedded controller 31 decides whether the user is in the state of being contactable with the bottom surface 102b on the basis of the result of detection by the acceleration sensor 34 and in a case where the user changes the state to the state of being contactable with the bottom surface 102b, the embedded controller 31 transmits the DITT switch command to the memory controller 42 via the interface IF 2.

### Operations in DITT Setting Processing

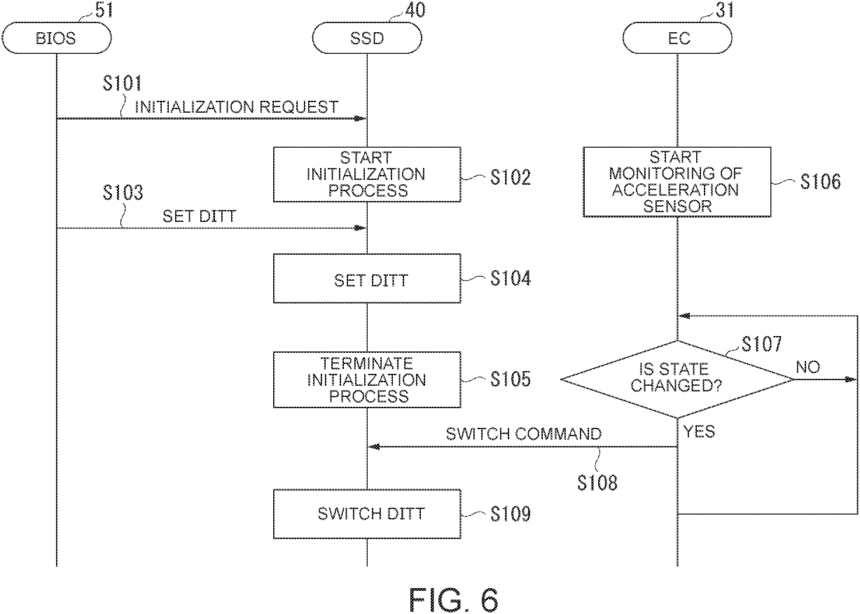

Next, operations in DITT setting processing that the information processing apparatus 10 executes will be described with reference to FIG. 6. FIG. 6 is a flowchart illustrating one example of the DITT setting processing pertaining to one embodiment of the present disclosure.

First, the BIOS 51 functions to start execution of a startup process and then to transmit an initialization request command to the SSD 40 via the interface IF 1 (the MVMe interface) (step S101). The SSD 40 acquires the initialization request command which is transmitted from the BIOS 51 and then starts execution of an initialization process (step S102) .

Next, the BIOS 51 functions to transmit the DITT set information (Set DITT) to the SSD 40 via the interface IF 1 (the MVMe interface) in the startup process (step S103). For example, the BIOS 51 functions to transmit the DITT set information which is used for setting the choices of two DITTs, that is, the DITT #1 and the DITT #2 to the SSD 40.

The SSD 40 acquires the DITT set information which is transmitted from the BIOS 51 and then sets the DITT #1 and the DITT #2 which are contained in the acquired DITT set information as DITTs which are usable in the thermal throttling function (step S104). In addition, the SSD 40 sets, for example, the DITT #1 actively as the default DITT.

The SSD 40 terminates execution of the initialization process and then enters a state of being communicable with the embedded controller 31 via the interface IF 2 (step S105).

On the other hand, the embedded controller 31 is started up and then starts monitoring by acquiring the sensor signals from the acceleration sensor 34 at a predetermined period (step S106).

The embedded controller 31 decides whether the use state of the information processing apparatus 10 is changed on the basis of a result of detection by the acceleration sensor 34 (step S107). For example, in a case where the value which indicates the motion of the information processing apparatus 10 is less than a predetermined value and it is possible to decide that the information processing apparatus 10 is in the stationary state, the embedded controller 31 decides that the user uses the information processing apparatus 10 in the state of placing the information processing apparatus 10 on the desk and so forth, that is, decides that the user is in the state of not being contactable with the bottom surface 102b. On the other hand, in a case where the value which indicates the motion of the information processing apparatus 10 is more than the predetermined value and it is possible to decide that the information processing apparatus 10 is not in the stationary state (in the state where the information processing apparatus 10 is moving though slightly), the embedded controller 31 decides that the user uses the information processing apparatus 10 in the state of putting the information processing apparatus 10 the user’s knees and so forth, that is, decides that the user is in the state of being contactable with the bottom surface 102b.

In a case where the embedded controller 31 decides that the use state of the information processing apparatus 10 is not changed (step S107: NO), the embedded controller 31 executes again the decision process in step S107.

On the other hand, in a case where the embedded controller 31 decides that the use state of the information processing apparatus 10 is changed (step S107: YES), the embedded controller 31 transmits the DITT switch command (Switch command) to the SSD 40 via the interface IF 2 (the SMBus interface) (step S108). For example, in a case where the embedded controller 31 decides that the user changes the state from the state where the user uses the information processing apparatus 10 with the information processing apparatus 10 being put on the user’s knees and so forth (that is, the user is in the state of being contactable with the bottom surface 102b) to the state where the user uses the information processing apparatus 10 with the information processing apparatus 10 being placed on the desk and so forth (that is, the user is in the state of not being contactable with the bottom surface 102b), the embedded controller 31 transmits the DITT switch command which indicates the instruction to switch to the DITT #2 to the SSD 40. In addition, in a case where the embedded controller 31 decides that the user changes the state from the state where the user uses the information processing apparatus 10 with the information processing apparatus 10 being placed on the desk and so forth (that is, the user is in the state of not being contactable with the bottom surface 102b) to the state where the user uses the information processing apparatus 10 with the information processing apparatus 10 being put on the user’s knees and so forth (that is, the user is in the state of being contactable with the bottom surface 102b), the embedded controller 31 transmits the DITT switch command which indicates the instruction to switch to the DITT #1 to the SSD 40. After transmission of the DITT switch command, the embedded controller 31 again executes the decision process in step S107.

Incidentally, in the decision process which is executed in the step S107 which comes first after startup, since the DITT #1 is set in the SSD 340 in the default state, in a case where the embedded controller 31 decides that the user uses the information processing apparatus 10 in a state of placing the information processing apparatus 10 on the desk and so forth (that is, the user is in the state of not being contactable with the bottom surface 102b), with the state where the user uses the information processing apparatus 10 with the information processing apparatus 10 being put on the user’s knees and so forth (that is, the state of being contactable with the bottom surface 102b) being set as the default state, the embedded controller 31 decides that the state is changed and then transmits the DITT switch command to the SSD 40.

The SSD 40 acquires the DITT switch command which is transmitted from the embedded controller 31 and then switches the DITT in accordance with the switching instruction which is based on the DITT switch command (step S109). For example, in a case where the SSD 40 acquires the DITT switch command which indicates the instruction to switch from the DITT #1 to the DITT #2, the SSD 40 sets the DITT which is to be made active to the DITT #2. On the other hand, in a case where the SSD 40 acquires the DITT switch command which indicates the instruction to switch from the DITT #2 to the DITT #1, the SSD 40 sets the DITT which is to be made active to the DITT #1.

As described above, the information processing apparatus 10 according to one embodiment of the present disclosure includes the BIOS memory 22 (one example of a first memory), the CPU 11 (one example of a first processor) and the embedded controller 31 (one example of a second processor). The BIOS memory 22 stores the BIOS (one example of a first program) as the program which is used to control hardware startup. The CPU 11 (one example of the first processor) executes the BIOS which is stored in the BIOS memory 22. In addition, the BIOS memory 22 stores a program (one example of a second program) that the embedded controller 31 would execute as a program which is different from the BIOS. The embedded controller 31 is a processor which is different from the CPU 11 and executes the program which is stored in the BIOS memory 22 so as to be executed by the embedded controller 31. Incidentally, the BIOS and the program that the embedded controller 31 executes may be stored into mutually different memories.

In addition, the information processing apparatus 10 includes the SSD 40 (one example of a memory drive device) which includes the temperature sensor 43, the rewritable flash memories 41 (each is one example of a third memory) and the memory controller 42 which controls the access to each flash memory 41 so as to suppress temperature rising in a case where the temperature which is sensed by the temperature sensor 43 reaches the predetermined DITT (one example of a temperature threshold value). Then, the CPU 11 executes the BIOS and thereby performs a threshold value setting process of transmitting the information (for example, the DITT set information) on the plurality of DITTs which serves as the choices from which one predetermined DITT is to be selected to the memory controller 42 of the SSD 40 via the interface IF 1 (one example of a first interface). In addition, the embedded controller 31 performs a threshold value selection process of transmitting the selection information (for example, the DITT switch command) for selection of one DITT which is to be set as the predetermined DITT from among the choices of the plurality of DITTs to the memory controller 42 of the SSD 40 via the interface IF 2 (one example of a second interface).

Thereby, since it becomes possible for the information processing apparatus 10 to dynamically change the DITT which is to be used in the thermal throttling function also after setting the DITT at activation of the BIOS, it becomes possible for the information processing apparatus 10 to suppress the performance degradation while suppressing the temperature rising of the SSD 40.

For example, the embedded controller 31 selects one DITT which is to be set as the predetermined DITT from among the plurality of DITTs on the basis of the use state of the information processing apparatus 10 in the threshold value selection process.

Thereby, it becomes possible for the information processing apparatus 10 to suppress the performance degradation in accordance with the use state of the information processing apparatus 10 while suppressing the temperature rising of the SSD 40.

For example, the embedded controller 31 further performs a decision process of deciding whether the user is in the state of being contactable with the bottom surface 102b (one example of a specific area) of the information processing apparatus 10. Then, the embedded controller 31 selects one DITT which is to be set as the predetermined DITT from among the plurality of DITTs on the basis of the result of decision which is obtained by performing the decision process in the threshold value selection process.

Thereby, it becomes possible for the information processing apparatus 10 to suppress the performance degradation in accordance with the use state of the information processing apparatus 10 while suppressing the temperature rising of the SSD 40 so as to meet the safety standards such as the UL standards and so forth depending on whether the user is in the state of being contactable with the bottom surface 102b.

In addition, the information processing apparatus 10 includes the acceleration sensor 34 (one example of a motion sensor) which is adapted to detect the motion of the information processing apparatus 10. Then, the embedded controller 31 decides whether the user is in the state of being contactable with the bottom surface 102b of the information processing apparatus 10 on the basis of the result of detection which is made by the acceleration sensor 34.

Thereby, it becomes possible for the information processing apparatus 10 to decide whether the user is in the state of using the information processing apparatus 10 with the information processing apparatus being placed on the desk or the user is in the state of using the information processing apparatus 10 with the information processing apparatus 10 being put on the user’s knees and so forth by detecting the motion of the information processing apparatus 10 and then to decide whether the user is in the state of being contactable with the bottom surface 102b.

Incidentally, the acceleration sensor 34 is one example of the motion sensor and the motion sensor is not limited to the acceleration sensor. In the information processing apparatus 10, for example, a gyro sensor, a tilt sensor and so forth may be used in place of or in addition to the acceleration sensor 34.

Specifically, for example, in a case where the embedded controller 31 decides that the user changes from the state of being contactable with the bottom surface 102b of the information processing apparatus 10 to the state of not being contactable with the bottom surface 102b, the embedded controller 31 transmits the selection information (for example, the DITT switch command) for selection of the DITT (for example, DITT #2) which is higher than the currently set DITT (for example, DITT #1) to the memory controller 42 of the SSD 40 in the threshold value selection process.

Thereby, in a case where the state is changed from the state where the user is contactable with the bottom surface 102b of the information processing apparatus 10 to the state where the user is not contactable with the bottom surface 102b, it becomes possible for the information processing apparatus 10 to dynamically switch to one DITT which is higher than the DITT which is set for the state of being contactable with the bottom surface 102b in accordance with the UL standards and therefore it becomes possible for the information processing apparatus 10 to suppress the performance degradation in comparison with a case of fixing to the DITT which is set for the state of being contactable with the bottom surface 102b.

In addition, in a case where the embedded controller 31 decides that the user changes from the state of not being contactable with the bottom surface 102b of the information processing apparatus 10 to the state of being contactable with the bottom surface 102b, the embedded controller 31 transmits selection information (for example, the DITT switch command) for selection of one DITT (for example, DITT #1) which is lower than the currently set DITT (for example, DITT #2) to the memory controller 42 of the SSD 40 in the threshold value selection process.

Thereby, in a case where the user changes the state from the state of not being contactable with the bottom surface 102b to the state of being contactable with the bottom surface 102b, it becomes possible for the information processing apparatus to dynamically switch to the DITT which is lower than the DITT which is set in the state of not being contactable with the bottom surface 102b in accordance with the UL standards and therefore it becomes possible for the information processing apparatus 10 to suppress the temperature rising of the SSD 40 so as to meet the safety standards such as the UL standards and so forth.

For example, the interface IF 1 is the NVMe interface. In addition, the interface IF 2 is the SMBus interface.

Thereby, since it becomes possible for the information processing apparatus 10 to set the plurality of DITTs in the SSD 40 from the BIOS 51 via the NVMe interface and thereafter to select any one of the plurality of DITTs under the control of the embedded controller 31 via the SMBus interface, it becomes possible for the information processing apparatus 10 to suppress the performance degradation while suppressing the temperature rising of the SSD 40 by utilizing existing hardware and interfaces.

Incidentally, although there is a possibility that the BIOS 51 would function to switch the DITT in place of the embedded controller 31 by using an SMM (System Management Mode). However, control of DITT switching is complicated and hang-up and BSoD (Blue Screen of Death) would be induced. In addition, although it is also possible to perform DITT switching by using Windows (registered trademark) Operating System or DPTF (Dynamic Platform and Thermal Framework) which works on the Windows (registered trademark), it is necessary to install software which is necessary for installation of a driver and so forth and it sometimes occurs that it becomes impossible to utilize DPTF on other OSs such as Linux (registered trademark) and so forth. According to one embodiment of the present disclosure, it becomes possible to perform software-independent DITT control by using existing hardware.

In addition, a control method for use in the information processing apparatus 10 includes executing the BIOS (one example of the first program) by the CPU 11 (one example of the first processor) and thereby, performing the threshold value setting process of transmitting information (for example, the DITT set information) on the plurality of DITTs which are used as the choices for selection of one predetermined DITT (one example of the temperature threshold value) to the memory controller 42 of the SSD 40 (one example of the memory drive device) via the interface IF (one example of the first interface) and performing the threshold value selection process of transmitting the selection information (for example, the DITT switch command) for selection of one DITT which is to be set as the predetermined DITT from among the plurality of DITTs to the memory controller 42 of the SSD 40 via the interface IF 2 (one example of the second interface) by the embedded controller 31 (one example of the second processor).

Thereby, it becomes possible for the information processing apparatus 10 to dynamically change the DITT which is used in the thermal throttling function also after setting one DITT at the activation of the BIOS and therefore it becomes possible for the information processing apparatus 10 to suppress the performance degradation while suppressing the temperature rising of the SSD 40.

Incidentally, in one embodiment, one example that switching is performed between two DITTs (the DITT #1 and the DITT #2) is described. However, such a configuration may be also made that three or more DITTs are set in the SSD 40 and DITT switching is performed among these three or more DITTs. For example, the information processing apparatus 10 may execute the thermal throttling function by performing switching among the three DITTs in accordance with the use state (a usage form). Specifically, by way of example, the information processing apparatus 10 may perform switching among the three DITTs depending on which mode is set among a clamshell mode, a tentorial mode and a tablet mode as the use state (the usage form).

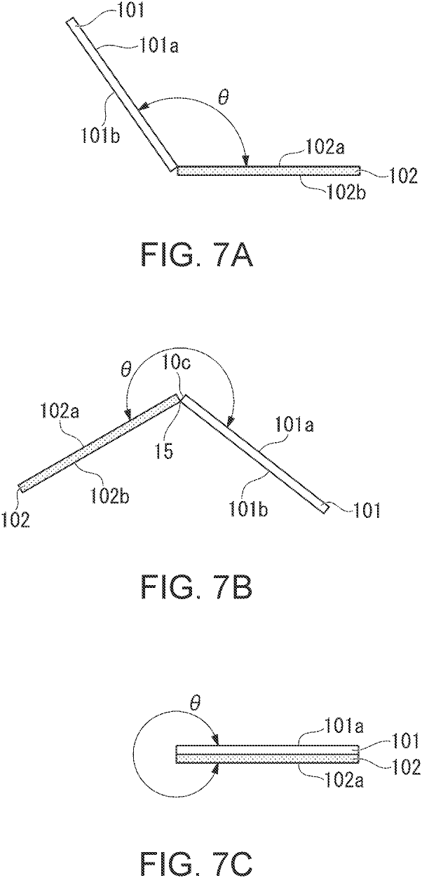

FIGS. 7A to 7C are diagrams illustrating examples of three use states (the usage forms) of the information processing apparatus 10. In FIG. 7A illustrates one example of the use state (the usage form) in the clamshell mode. The use state in the clamshell mode corresponds to the use state of the information processing apparatus 10 which is illustrated in FIG. 1. For example, the information processing apparatus 10 decides that the clamshell mode is set in a case where the open angle θ is 10° < θ ≤ 180° by way of example. The information processing apparatus 10 detects the open angle θ by using an angle sensor (not illustrated) and so forth. In FIG. 7B illustrates one example of the use state (the usage form) in the tentorial mode. For example, the information processing 10 decides that the tentorial mode is set in a case where the open angle θ is 180° < θ ≤ 330° by way of example. In FIG. 7C illustrates one example of the use state (the usage form) in the tablet mode. Although the open angle is typically 360° in the tablet mode, the information processing apparatus 10 decides that the tablet mode is set in a case where the open angle θ is 330° < θ ≤ 360° by way of example.

The information processing apparatus 10 is used generally by being placed on the desk in the clamshell mode. In addition, the information processing apparatus 10 is used in a state of being held by the user in many cases in the tablet mode. The information processing apparatus 10 is generally used by being placed on the desk in the tentorial mode. However, since the entire of the bottom surface 102b is not hidden by the surface on which the information processing apparatus 10 is placed differently from the state in the clamshell mode, it does not mean that the user is not contactable with the bottom surface 102b. In a case of performing switching among three DITTs in accordance with the use state (the usage form) by setting the temperature threshold value in the clamshell mode to a DITT #a, setting the temperature threshold value in the tentorial mode to a DITT #b and setting the temperature threshold value in the tablet mode to a DITT #c, the values of the respective DITTs are set such that, for example, a relation “DITT #a > DITT #b > DITT #c” is established.

Although one embodiment of the present disclosure is described in detail as above, a concrete configuration is not limited to the above-described configuration and it is possible to perform design changing and so forth in a variety of ways within a range not deviating from the gist of the present disclosure.

Incidentally, the embedded controller 31 is one example of a microcomputer as the processor which is different from the CPU 11 and is not limited to the processor of the above-mentioned type.

In addition, although in one embodiment, the example that the MVMe interface is used as one example of the interface LF 1, the interface IF 1 is not limited to the MVMe interface and another interface which accords with the specifications of the SSD 40 which is connected to that interface. In addition, although an example that the SMBus interface is used as one example of the interface IF 2 is described, the interface IF 2 is not limited to the SMBus interface and, for example, another interface such as an I2C (Inter-Integrated Circuit) bus and so forth may be used and an interface which utilizes a change in voltage, a voltage pulse and so forth may be also used.

In addition, the information processing apparatus 10 has a computer system which is built therein. Then, each program for realizing each function of each constitutional element that the information processing apparatus 10 includes may be recorded into a computer readable recording medium, each program which is recorded into the recording medium may be read into the computer system and may be executed, and thereby each process which is assigned to each constitutional element that the information processing apparatus 10 includes may be performed. Here, “each program which is recorded into the recording medium may be read into the computer system and may be executed” includes installation of each program into the computer system. Here, “the computer system” shall include the OS and the hardware such as the peripherals and so forth. In addition, “the computer system” may also include a plurality of computer devices which is mutually connected over a network which includes communication lines such as the Internet, a WAN, a LAN, a leased line and so forth. In addition, “the computer readable recording medium” means portable media such as a flexible disc, a magneto-optical disc, a ROM, a CD-ROM and so forth and storage devices such as a hard disc and others which are built in the computer system. The recording medium which records the program in this way may be a non-transitory recording medium such as the CD-ROM and so forth.

In addition, an internally or externally installed recording medium which is accessible from a distribution server for distribution of the program concerned is also included in the recording medium. Incidentally, a configuration that one program is divided into a plurality of sections, these sections are downloaded at mutually different timings and then are integrated together by respective constitutional elements that the information processing apparatus 10 includes may be also made and distribution servers for distributing the respective divided sections of the program may be different from one another. Further, “the computer-readable recording medium” shall also include media which hold the program for a definite time period such as a server and a volatile memory (RAM) which serves as a client in the computer system in a situation where the program is transmitted over the network. In addition, the program may be a program which is adapted to realize some of the above-described functions. Further, the program may be also a program which makes it possible to realize the above-mentioned functions by being combined with a program which is already recorded in the computer system, that is, a so-called differential file (a differential program).

In addition, some of or all the respective functions that the information processing apparatus 10 according to one embodiment includes may be realized as an integrated circuit such as an LSI (Large Scale Integration) and so forth. The respective functions may be implemented by a processor individually and/or some of or all the functions may be mutually integrated and then implemented by a processor. In addition, a technique of circuit integration may be realized by a private circuit or a general-purpose processor, not limited to the LSI. In addition, in a case where a novel circuit integration technology which realizes an integrated circuit which will take the place of the existing LSI emerges owing to advancement of the semiconductor technology, the integrated circuit which is realized by the novel technology may be also used.

What is claimed is:

1. An information processing apparatus comprising:
a first processor that executes a hardware startup process;
a second processor separate from the first processor; and
a memory interface which includes a temperature sensor, the memory interface that interfaces with a memory, wherein
the memory interface, when a temperature sensed by the temperature sensor reaches a predetermined temperature threshold value, throttles performance of the memory,
the first processor executing the hardware startup process includes transmitting a plurality of temperature threshold values to the memory interface via a first interface, and
the second processor, in response to an event, transmits selection information to the memory interface via a second interface different from the first interface, the selection information indicating selection of one of the plurality of temperature threshold values to be set as the predetermined temperature threshold value.

2. An information processing apparatus comprising:
a first memory which stores a first program for controlling startup of hardware;
a first processor which executes the first program which is stored in the first memory;
a second memory which stores a second program which is different from the first program;
a second processor which is different from the first processor and executes the second program which is stored in the second memory; and
a memory drive device which includes a temperature sensor, a third rewritable memory and a memory controller which controls access to the third memory so as to suppress temperature rising in a case where a temperature which is sensed by the temperature sensor reaches a predetermined temperature threshold value, wherein
the first processor executes the first program which is stored in the first memory and thereby performs a threshold value setting process of transmitting information on a plurality of temperature threshold values which is used as choices from which the predetermined temperature threshold value is to be selected to the memory controller via a first interface, and
the second processor executes the second program which is stored in the second memory and thereby performs a threshold value selection process of transmitting selection information for selection of a temperature threshold value which is to be set as the predetermined temperature threshold value from among the choices of the plurality of temperature threshold values to the memory controller via a second interface.

3. The information processing apparatus according to claim 2, wherein
the second processor, in the threshold value selection process, selects one temperature threshold value which is to be set as the predetermined temperature threshold value from among the plurality of temperature threshold values on the basis of a use state of the information processing apparatus.

4. The information processing apparatus according to claim 2, wherein
the second processor:
executes the second program which is stored in the second memory and thereby further performs a decision process of deciding whether a user is in a state of being contactable with a specific area of the information processing apparatus; and
in the threshold value selection process, selects one temperature threshold value which is to be set as the predetermined temperature threshold value from among the plurality of temperature threshold values on the basis of a result of decision which is obtained by performing the decision process.

5. The information processing apparatus according to claim 4, further comprising:
a motion sensor which is adapted to detect a motion of the information processing apparatus, wherein
the second processor, in the decision process, decides whether the user is in the state of being contactable with the specific area of the information processing apparatus on the basis of a result of detection by the motion sensor.

6. The information processing apparatus according to claim 4, wherein
the second processor, in a case where changing from the user’s state of being contactable with the specific area of the information processing apparatus to a user’s state of not being contactable with the specific area is decided by performing the decision process, transmits the selection information for selection of a temperature threshold value which is higher than the currently set temperature threshold value in the threshold value selection process to the memory controller.

7. The information processing apparatus according to claim 4, wherein
the second processor, in a case where changing from the user’s state of not being contactable with the specific area of the information processing apparatus to the user’s state of being contactable with the specific area is decided by performing the decision process, transmits the selection information for selection of a temperature threshold value which is lower than the currently set temperature threshold value in the threshold value selection process to the memory controller.

8. The information processing apparatus according to claim 2, wherein
the first interface is an Non Volatile Memory Express (NVMe) interface, and
the second interface is an System Management Bus (SMBus) interface.

9. The information processing apparatus according to claim 2, wherein
the first program is a Basic Input/Output System (BIOS) program.

10. A control method for use in an information processing apparatus which includes a first memory which stores a first program for controlling startup of hardware, a first processor which executes the first program which is stored in the first memory, a second memory which stores a second program which is different from the first program, a second processor which is different from the first processor and executes the second program which is stored in the second memory and a memory drive device which includes a temperature sensor, a third rewritable memory and a memory controller which controls access to the third memory so as to suppress temperature rising in a case where a temperature which is sensed by the temperature sensor reaches a predetermined temperature threshold value, the method comprising:
executing the first program which is stored in the first memory and thereby performing a threshold value setting process of transmitting information on a plurality of temperature threshold values which is used as choices for selection of the predetermined temperature threshold value to the memory controller via a third interface by the first processor; and
executing the second program which is stored in the second memory and thereby performing a threshold value selection process of transmitting selection information for selection of a temperature threshold value which is to be set as the predetermined temperature threshold value from among the choices of the plurality of temperature threshold values to the memory controller via a second interface by the second processor.
